(19) United States
(12) Patent Application Publication
(10) Pub. No.: US 2005/0006223 A1
(43) Pub. Date: Jan. 13, 2005

(54) Sputter deposition masking and methods

(76) Inventors: Robert Nichols, Santa Rosa, CA (US); Justin Mosier, Santa Rosa, CA (US)

Correspondence Address: DUANE MORRIS LLP, Suite 700, 1667 K. Street, N.W., Washington, DC, 20006, US

(21) Appl. No.: 10/840,274

(22) Filed: May 7, 2004

Related U.S. Application Data
(60) Provisional application No. 60/468,264, filed on May 7, 2003.

(51) Int. Cl. C23C 14/00; C23C 14/32

(52) U.S. Cl. 204/192.1; 204/298.02

(57) ABSTRACT

A masking system and method for attaining uniformity or controlled non-uniformity in thin film coatings among an array of substrates in a sputter deposition system. The masking system includes collimators formed by intersecting blades having non-uniform depth, thickness, and/or spacing. The position of the mask may also be fixed relative to the position of the substrates in the system. The system is particularly suitable for attaining such coatings among an array of non-planar or complex-shaped substrates such as automotive lamps, industrial lamps, or reflectors.

### CLAIM OF PRIORITY

This application claims the priority of U.S. Provisional Patent Application No. 60/468,264 filed May 7, 2003, the content of which is incorporated herein by reference.

### BACKGROUND OF THE INVENTION

The present invention relates to systems and methods for depositing material onto substrates to form thin film coatings. More particularly, the present invention relates to such systems and methods of deposition where a high level of uniformity or controlled non-uniformity of the coating is required among an array of substrates.

Sputtering deposition systems and processes have found widespread use in depositing thin film coatings on arrays of substrates in view of the suitability of such sputtering systems for depositing dense, robust, high layer count dielectric thin films. Sputtering deposition systems are particularly suited for depositing thin film coatings on complex shaped substrates such as automotive lamps, industrial lamps, and curved reflectors, and for depositing thin film coatings on arrays of substrates where a high degree of uniformity, or controlled non-uniformity, of the coating among the substrates in the array is desired.

Typical sputtering deposition processes include “batch processes” in which the substrates are transported past a source of coating material by a substrate carrier such as a rotating drum or disk, and “in-line” processes in which a transporting mechanism carries the substrates past the source in a substantially straight path. Such processes are widely used in industry to apply coatings to arrays of substrates.

For example, U.S. Pat. No. 5,714,009 to Bartolomei, commonly assigned with the present application, discloses such processes. The Bartolomei patent, incorporated herein by reference, discloses systems for producing coatings by microwave-assisted sputtering. In the disclosed processes, both rotating drums and linear transport mechanisms are used to transport substrates past sputtering targets and microwave energized plasma generators in a reactive sputtering process. FIG. 1 depicts one embodiment.

Referring to FIG. 1, a sputtering chamber 21 contains a rotatable drum 22 which carries substrates 23 in a first motion parallel to the direction of the arrow 24 past an elongated sputtering target 25 and past an elongated microwave-energized plasma generator 26. The substrates 23 are arranged in rows that are parallel to the substrate motion and columns perpendicular to that motion. The target 25 and plasma generator 26 are typically mounted on the chamber wall as illustrated in FIG. 1. Other sputtering targets and plasma generators, not shown, may also be mounted on the chamber wall. Usually additional targets and plasma generators will have the same vertical dimensions and will be mounted in the same vertical position as the targets and generators shown in FIG. 1.

During the sputtering process, material is sputtered from the sputtering target 25 onto the substrates 23. In reactive sputtering processes, the sputtered material is reacted with a reacting gas in the chamber to produce the desired coating. It is almost always necessary to assure that all of the substrates receive a coating that has nearly the same properties, or have controlled differences in the properties.

For example, to attain a substantially uniformly thick layer the amount of deposited material per unit area on each substrate must generally be within a prescribed limit. The amount of material deposited on a given substrate depends on the location of the substrate in the direction of the longer length of the target. The arrow 27 indicates this direction, referred to throughout the application as the “z direction”. The deposition of material is highest at the center of the sputtering target and decreases to zero at extreme distances from the center. In FIG. 1, the lines 28 and 29 at the ends of arrow 27, bound the region within which uniformity of deposition remains within tolerance. It is typically necessary to restrict the size of the region in the z direction so that the difference between the deposition on the center substrates and on the end substrates lies within the acceptable tolerance. Thus, the number of substrates in each column is the number that may be mounted between these limits. This number is reduced in processes in which a tighter tolerance is imposed.

FIG. 2 is a graph illustrating the correlation between the amount of deposited material and the position of the substrate along the vertical column (i.e. the position in the z direction). The curve 30 in FIG. 2 applies to the batch process of FIG. 1 and shows the amount of deposited material per unit area at substrate locations along the z direction. The target generating the curve disclosed in FIG. 2 is assumed to be an “ideal” target, i.e., the target has a uniform rate of sputtering at all locations.

The deposition of material on the substrates is highest at the point 31, which lies opposite the center of the target. At the locations 32 that lie opposite the ends of the target the deposition is reduced to approximately half of the center value. The arrows 33 are provided to indicate the tolerance for the process. The limits of the area within which substrates may be placed and still meet the tolerance are reached when the difference between the maximum (center) value and the value at the limit equals the tolerance. The lines 34 are provided to show the limits. The tolerance is considerably less than 50%, and the limits must be displaced inward from the ends of the elongated target resulting in a region of deposition less than the target length. It should be noted that the rate of sputtering from a real target is not perfectly uniform, therefore, the limits must be moved inward farther than shown in FIG. 2 when considering a real target.

The production rate of a coating process is proportional to the number of rows of substrates being coated at one time. The number of rows is limited by the target size. Therefore, high production rates require large targets. Large targets are expensive, difficult to maintain, subject to uniformity variations along their length, and require large and expensive power supplies. Furthermore, large targets are more vulnerable to arcing, than small targets which interferes with the stability of the coating process and degrades the quality of the deposited film.

Masking is one known method of improving the coating characteristics among an array of substrates in a sputtering deposition process as disclosed in U.S. Pat. No. 6,485,616 BI to Howard et al., commonly assigned with the present application, and incorporated herein by reference. As disclosed in Howard et al., it is known to use masking to prevent deposition of low energy material and material which impinges at large angles of incidence resulting in an improvement of film quality.

Masking may improve the uniformity or controlled non-uniformity of thin film coatings in an array of substrates by shielding the substrates from atoms of the deposition material having a high angle of incidence relative to the substrates. However, prior art masks such as collimators fail to eliminate periodic variations of coating thickness among substrate arrays in the z direction, and are inadequate in providing uniform or controlled non-uniform thickness in coatings on complex-shaped substrates. Thus a need remains for a masking system that provides uniform or controlled non-uniform coatings on an array of substrates in a sputtering deposition system. A need also remains for a masking system for providing such coatings on complex-shaped substrates.

Accordingly, it is an object of the present invention to obviate many of the above problems in the prior art and to provide a novel masking system and method for sputtering deposition systems.

It is another object of the present invention to provide a novel masking system and method wherein the dimensions of the mask are correlated with the size and shape of the substrates.

It is yet another object of the present invention to provide a novel masking system and method wherein the depth, thickness, and/or spacing of the blades in the mask may be varied.

It is still another object of the present invention to provide a novel masking system and method having non-uniform cells.

It is a further object of the present invention to provide a novel masking system and method wherein the position of the mask is fixed relative to the substrates.

It is yet a further object of the present invention to provide a novel masking system and method wherein the position of the mask varies relative to the target.

It is still a further object of the present invention to provide a novel masking system and method for providing uniform coatings in sputtering deposition systems on an array of planar substrates.

It is an additional object of the present invention to provide a novel masking system and method for providing uniform coatings in sputtering deposition systems on an array of complex-shaped substrates.

These and many other objects and advantages of the present invention will be readily apparent to one skilled in the art to which the invention pertains from a perusal of the claims, the appended drawings, and the following detailed description of the preferred embodiments.

### BRIEF DESCRIPTION OF THE DRAWINGS

FIG. 1 is a pictorial view in partial section of a prior art sputter deposition system.

FIG. 2 is an illustration showing the variation of deposition thickness in relation to a point on a substrate relative to the sputtering target of the system shown in FIG. 1.

FIG. 3 is a pictorial view of a prior art collimator attached to a sputtering target.

FIG. 4 is a cross-sectional view taken through 18-18 of FIG. 3.

FIG. 5 is an illustration showing the distribution of angles of material sputtered from targets with and without collimators.

FIG. 6 is an illustration showing a side view relationship between the collimator and target of FIG. 3 and a substrate.

FIG. 7 is an illustration showing the variation of deposition thickness on the substrate of FIG. 6.

FIG. 8 is a pictorial view of a section of a mask according to one aspect of the present invention.

FIG. 9a is a pictorial view of a section of a mask according to one aspect of the present invention.

FIG. 9b is a cross-section of an adjustable depth blade of FIG. 9a.

FIG. 10a is a pictorial view of a section of a mask according to one aspect of the present invention.

FIG. 10b is a cross-section of a variable thickness blade of FIG. 10a.

FIG. 11a is a side view of a lamp reflector.

FIG. 11b is a front view of a lamp reflector.

FIG. 12 is a partial side view of a prior art system for coating lamp reflectors.

FIG. 13 is a reproduction of a photograph showing a partial view of a sputter deposition system according to one aspect of the present invention.

FIG. 14 is a partial front view of a sputter deposition system according to one aspect of the present invention.

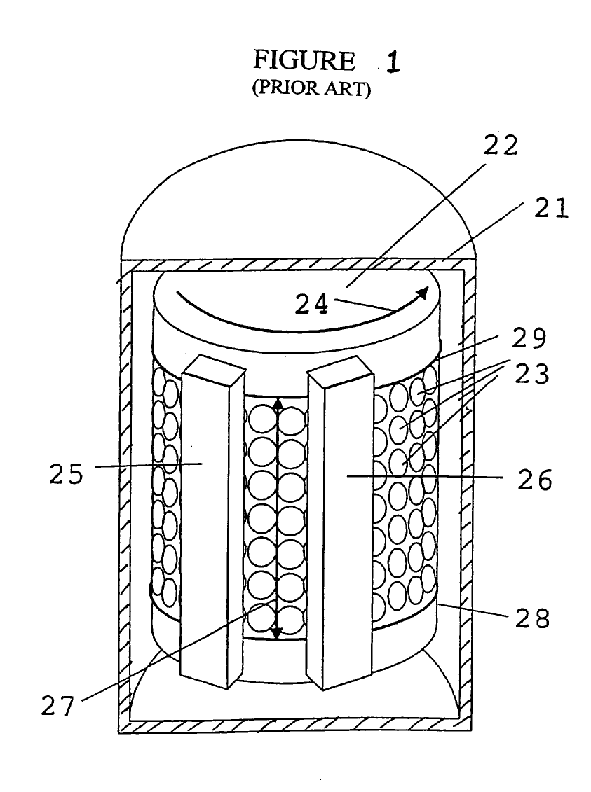

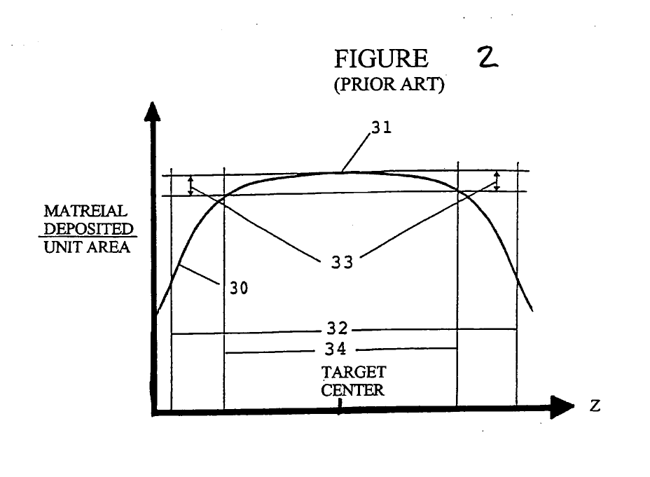

### DESCRIPTION OF PREFERRED EMBODIMENTS

With reference to the drawings, like numerals represent like components throughout the several drawings. The present invention relates to masking systems and methods for sputtering deposition of thin film coating on arrays of substrates. The present invention is particularly suited for providing uniform or controlled non-uniform coatings on non-planar or complex-shaped substrates such as automotive lamps, industrial lamps, and reflectors.

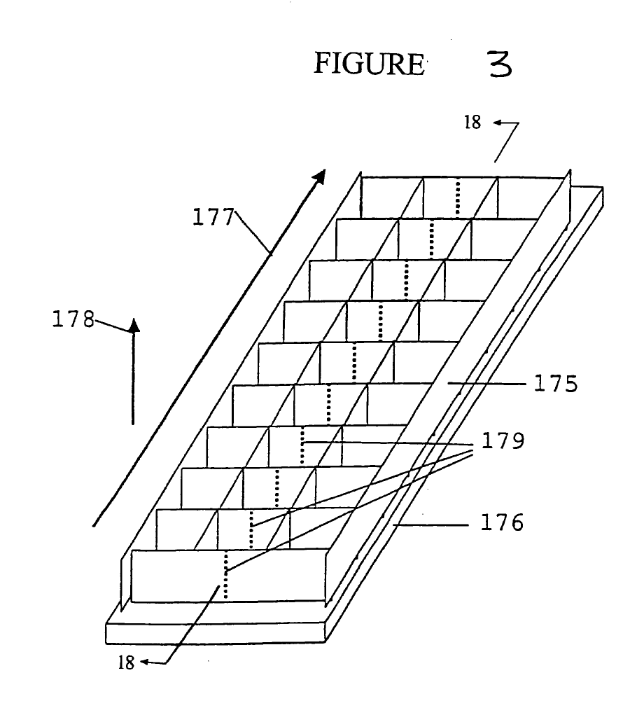

Masking systems for sputter deposition processes are well known for shielding the substrates from deposition material having a high angle of incidence. As illustrated in FIG. 3, prior art masks or “collimators” include strips (or “blades”) of rigid material such as metal attached to form a grid of substantially rectangular “cells”. With reference to FIG. 3, the collimator 175 includes multiple blades 180 forming the cells 174. The blades 180 are uniform in thickness and depth, and are uniformly spaced to form uniformly shaped cells 174. The collimator 175 is adjacent an elongated sputtering target 176 that may be part of a magnetron target assembly. Typically the collimator 175 is attached so that position of the collimator with respect to the target remains fixed during the sputtering process. The target 176 with the collimator 175 is typically mounted on the wall of a coating chamber with the long axis of the target generally along the z direction perpendicular to the direction of first motion as indicated by the arrow 177. The y direction perpendicular to the target emitting surface and parallel to the faces of the collimator strips is indicted by the arrow 178.

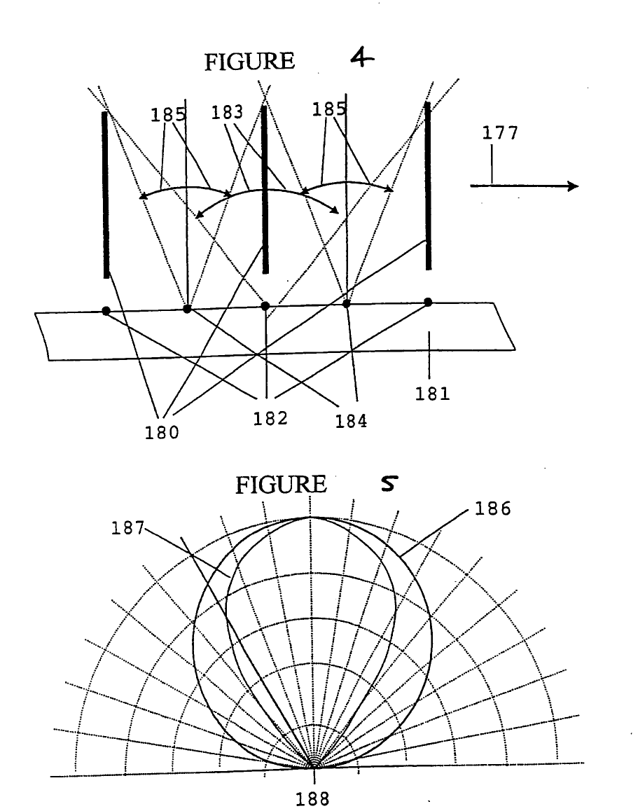

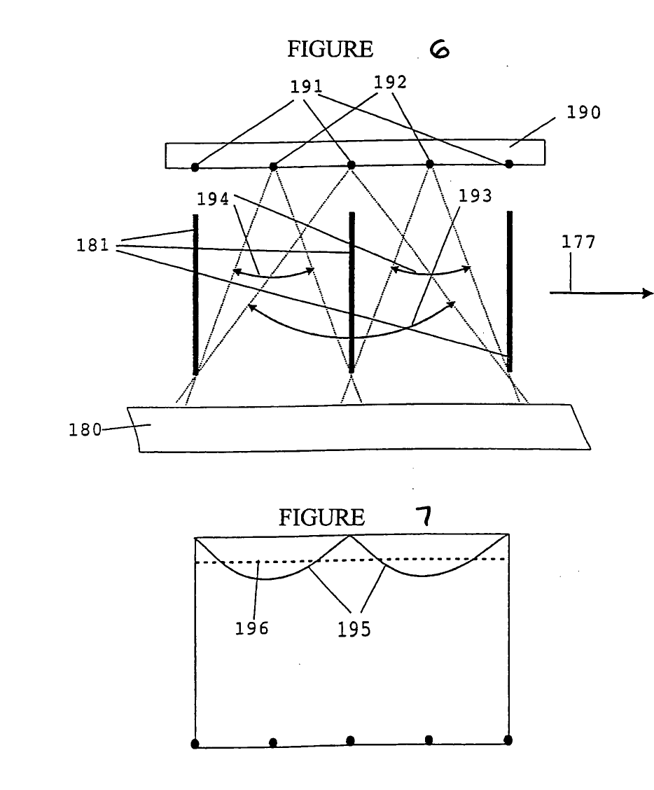

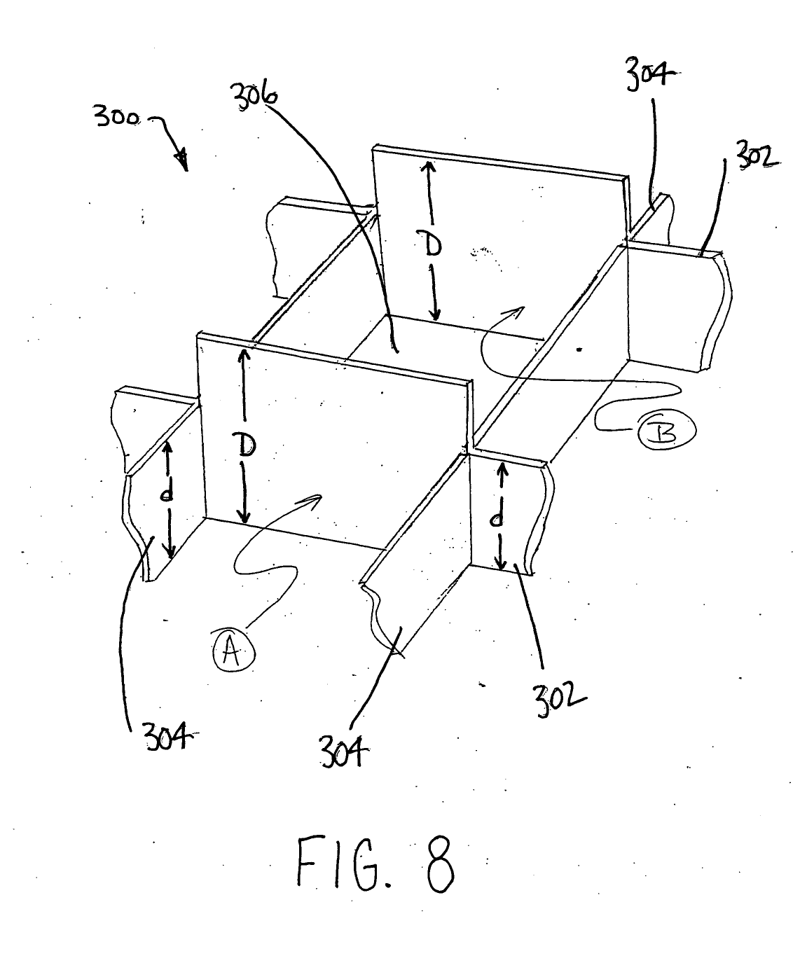

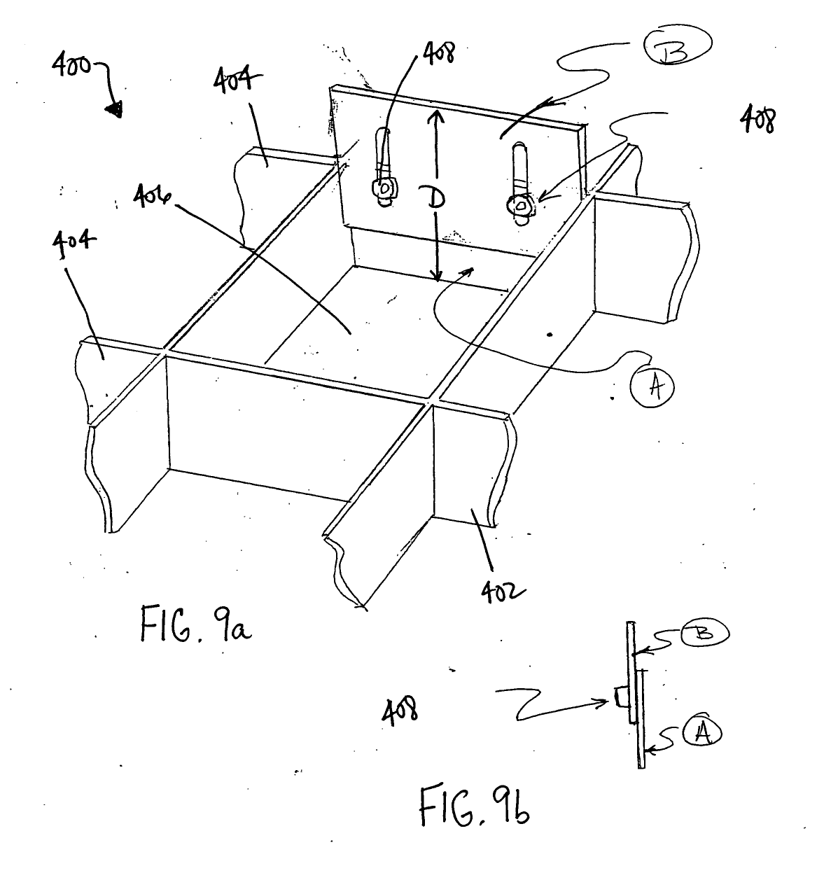

FIG. 4 is a cross-section through the collimator of FIG. 3 in a plane parallel to the y-z plane and passing through the dotted lines 179 of FIG. 3. The z-axis lies in the direction of the arrow 177. The blades 180 of the collimator are separated from the target and block a portion of the emissions from the surface of the sputtering target 176. As shown, the collimator blocks material that is emitted from the target at high angles with respect to the y direction (i.e. perpendicular to the target surface). For emissions from the points 182, for example, the collimator blocks emissions having angles greater than the angles 183. The collimator also blocks some emissions at very small angles due to the width of the blades of the collimator. Similarly, emissions from point 184 are blocked if the emitted angle with respect to the y direction is greater than the angle 185. Thus, the blocking effects of the collimator depend on the location of the target from which emission occurs, but in general an emission having an angle greater than the angle 183 will not reach the substrate.

FIG. 4 depicts only one plane parallel to the y-z plane. When all emission planes are considered, the effect of the collimator on the angular distribution of emitted material may be obtained as shown in FIG. 5 in the plot of the beam patterns produced by the target and collimator considering all points on the target surface. The plot 186 shows a typical beam pattern of a target without a collimator and the plot 187 shows a typical beam pattern produced by a sputtering target assembly including a collimator. Both plots 186 and 187 are polar plots in which the coordinates of a point are the amount or emission per unit solid angle and the angle made with the y direction by a line pointing in the direction of the emission. The lines of equal emission per unit solid angle are dotted circles in FIG. 5, and the lines of equal emission angle are the dotted lines radiating from the origin 188. A comparison of the plots 186 with 187 indicates that a collimator increases the percentage of material moving from the target to the substrate emitted with a relatively small angle to the y direction.

FIG. 6 illustrates the section of FIG. 4 and includes a substrate 190 upon which the emitted material falls. Collimator blades 180 are located between the emitting surface of the target and the substrate. The points 191 on the substrate are located directly above the blades, and points 192 are located on the substrate midway between the points 191. The collimator causes a variation in the thickness of the deposited coating over the substrate 190 because the angle 193 includes the region within which material emitted from the target will strike the point 191 while point 192 will receive material emitted in the smaller angle 194 and thus the thickness of the deposited material at points 192 will be less than the thickness of the deposition at points 191.

The curve 195 of FIG. 7 is a plot of relative deposition thickness as a function of the z coordinate for points in the plane of FIG. 6. The ordinate is the relative deposition, expressed as the ratio between the thickness and the maximum thickness. The abscissa is the z coordinate of the point whose thickness is plotted. The locations of the points 191 and 192 are indicated by solid dots.

In many prior art processes, the beneficial result of low incidence angles on film quality is achieved at the expense of a loss of uniformity of the film thickness. In one aspect of the present invention, improvement in the uniformity, or controlled non-uniformity, of the thickness of the coating among an array of substrates may be attained by providing a masking systems having selectively varied depth, thickness and/or spacing of the blades in the collimator. The physical characteristics of the collimator are selectively varied according to the physical characteristics of the substrates to be coated.

FIG. 8 illustrates a masking system according to one aspect of the present invention. With reference to FIG. 8, a section 300 of a collimator includes the blades 302 intersecting with the blades 304 to form the cell 306 bounded by the generally planar surfaces of the blades 302,304. The depth “D” of a portion of the blades 302 is greater than the depth “d” of the remaining portions of the blades 302,304. The depth of the blades may be varied in the grid of cells in the collimator as necessary to attain the desired coating thickness among the array of substrates. The surfaces of the blades forming the walls of the cells may be generally planar as shown in FIG. 8, or may be non-planar.

FIG. 9a illustrates a masking system according to another aspect of the present invention. With reference to FIG. 9a, a section 400 of a collimator includes the blades 402 intersecting with the blades 404 to form the cell 406 bounded by the generally planar surfaces of the blades 402,404. The depth “D” of a portion of one of the blades 402 is greater than the depth “d” of the remaining portions of the blades 402,404. The depth “D” of the blade 402 may be adjusted by moving the relative positions of portions “A” and “B”. FIG. 9b illustrates a cross-section of the adjustable portion of blade 402. Any conventional means for fixing the position of portions “A” and “B” may be used such as set screws 408. In this embodiment, the depth “D” may be varied in the grid of cells in the collimator as necessary to attain the desired coating thickness among the array of substrates. The surfaces of the blades forming the walls of the cells may be generally planar as shown in FIG. 9a, or may be non-planar.

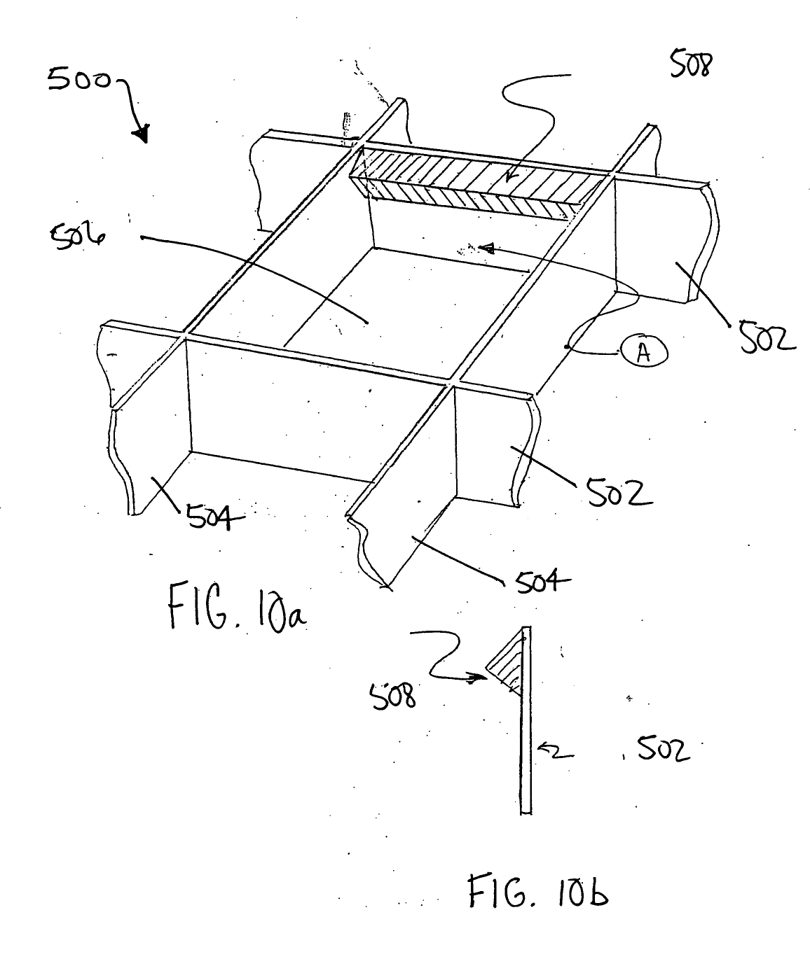

FIG. 10a illustrates a system according to another aspect of the present invention. With reference to FIG. 10a, a section 500 of a collimator includes the blades 502 intersecting with the blades 504 to form the cell 506 bounded by the generally planar surfaces of the blades 502,504. The thickness of one or more of the blades 502,504 may be varied. As illustrated in FIG. 10b, the thickness of the blade 502 is varied by attaching an elongated wedge piece 508 near one edge of the blade. The thickness of the blades may also be varied by attaching pieces of different shapes such as pieces having semi-circular or rectangular cross-sections and the thickness variation may extend over a portion of the depth of the blades or the entire depth of the blades. The thickness of the blades may be varied as necessary among the various blades in the collimator to attain the desired coating on the array of substrates.

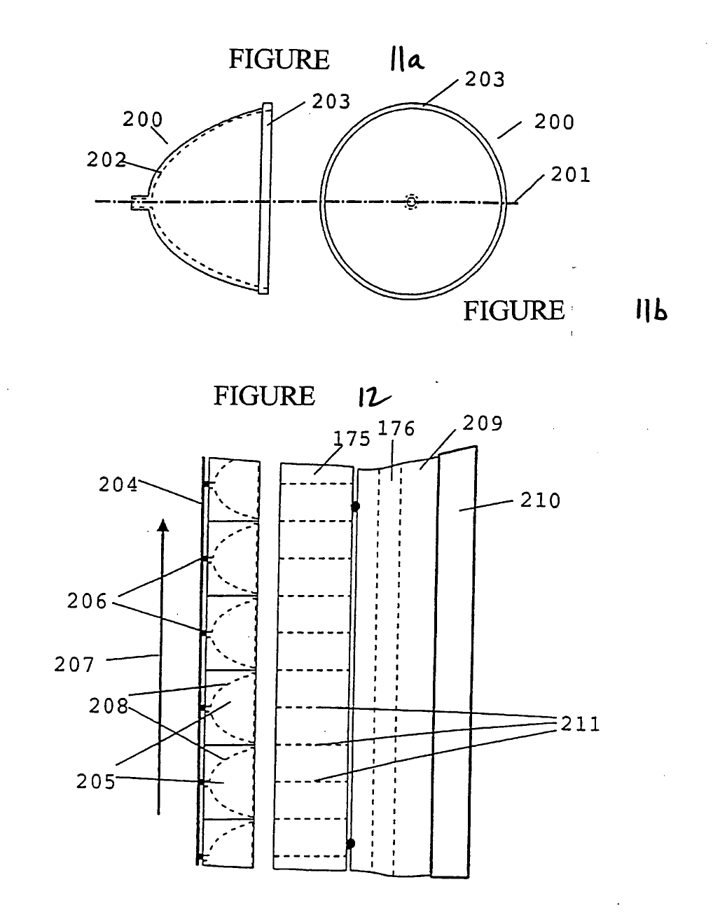

Use of a collimator is known to improve the film quality of non-planar or complex-shaped substrates. FIGS. 11a and 11b illustrate a typical lamp reflector 200 which is symmetrical with respect to rotation about the axis 201, and a plane passing through the axis intersects its inner reflecting surface 202 to form a parabola or ellipse. A typical prior art masking system for coating an array of lamp reflectors 200 is illustrated in FIG. 12. As shown in FIG. 12, the substrate holders 205 carry substrates 208 in close proximity to the target assembly 209. A collimator 175 may be attached to the target assembly so that the position of the collimator 175 is fixed relative to the target assembly 209. The blades 211 within the collimator are uniform in depth.

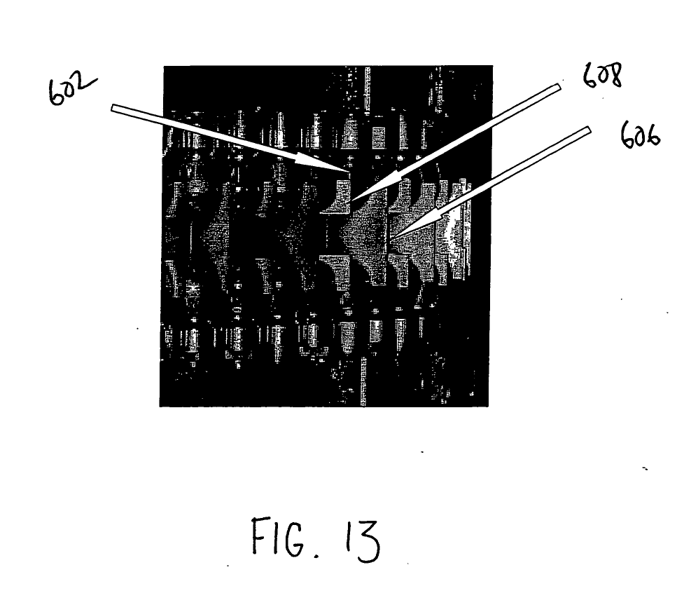

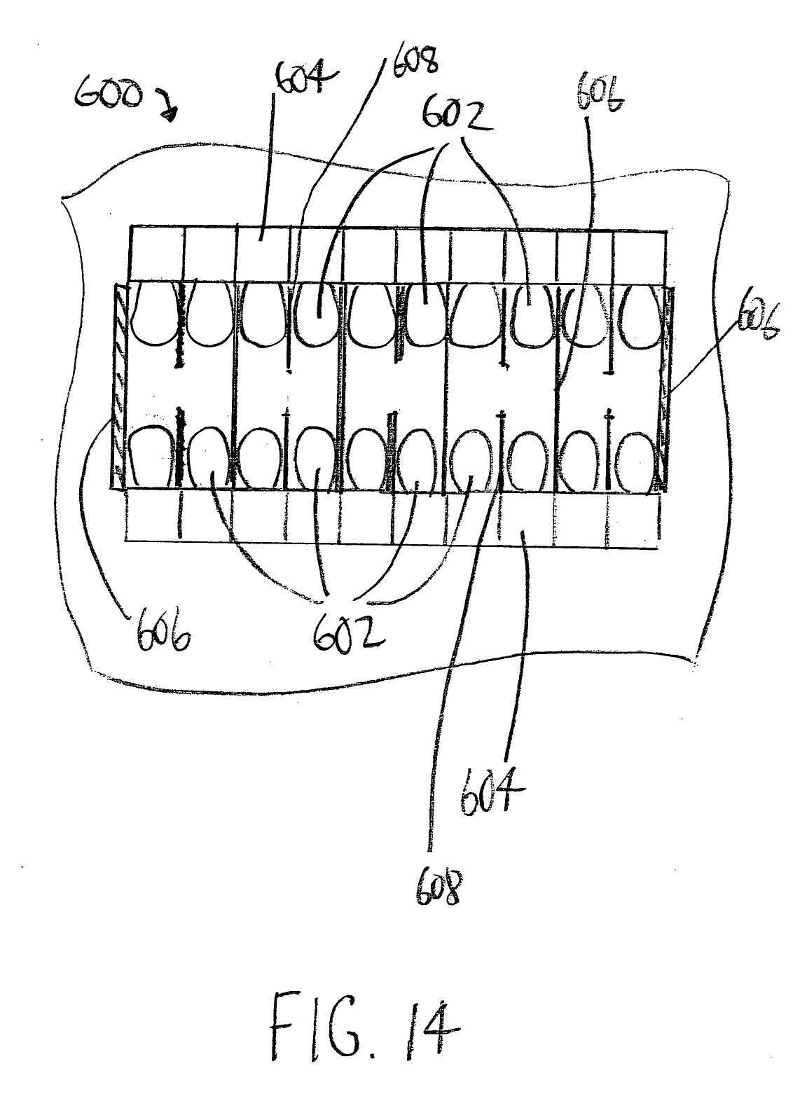

It has been discovered in sputtering systems for coating an array of non-planar or complex-shaped substrates such as lamp reflectors or lamp burners that the uniformity or controlled non-uniformity of the coating among the array of substrates may be improved by fixing the position of the mask to the individual substrates. FIGS. 13 and 14 illustrate another embodiment of the present invention. With reference to FIGS. 13 and 14, a portion 600 of a generally cylindrical substrate carrier is shown carrying an array of lamp burners 602. Each lamp burner 602 is secured to the carrier by a substrate holder 604. Each lamp burner is shielded on one side by a first side mask 606 and on the other side by a second side mask 608. The side masks 606,608 are generally planar in the illustrated embodiment but may be any suitable shape for attaining the desired masking of the substrates. The side masks 606,608 may be carried by the carrier so that the position of the side masks is fixed relative to the lamp burners 602. The substrate holders 604 may also include a means (not shown) for rotating the lamp burners 602 about the longitudinal axis of the burners. The carrier may be rotated to transport the burners 602 and the side masks 606,608 past a sputtering target (not shown).

While preferred embodiments of the present invention have been described, it is to be understood that the embodiments described are illustrative only and that the scope of the invention is to be defined solely by the appended claims when accorded a full range of equivalence, many variations and modifications naturally occurring to those of skill in the art from a perusal hereof.

1. In a system for depositing a layer of material on an array of substrates carried on a substrate carrier past one or more sources of deposition material wherein relative distribution of the deposited material on each of the substrates in the array is altered by a mask, the improvement wherein the mask is carried by the substrate carrier.

2. The system of claim 1 wherein said carrier is a generally cylindrical drum.

3. The system of claim 1 wherein said carrier is a disk.

4. The system of claim 1 wherein the source of deposition material is a sputtering target.

5. The system of claim 1 wherein the substrates include a curved surface and the mask alters the rate of deposition so that the thickness of the deposited layer of material is substantially uniform on the curved surface.

6. The system of claim 5 wherein the substrates are lamp components.

7. The system of claim 1 wherein the substrates include a curved surface and the mask alters the rate of deposition so that the thickness of the deposited layer of material is selectively non-uniform on the curved surface.

8. The system of claim 1 wherein the mask alters the rate of deposition so that the thickness of the deposited layer of material on each substrate is substantially uniform.

9. The system of claim 1 wherein the mask alters the rate of deposition so that the thickness of the deposited layer of material on each substrate is selectively non-uniform.

10. In a thin film deposition system including (i) a sputtering target, (ii) one or more substrates carried by a substrate carrier past the sputtering target, and (iii) a mask, the improvement wherein the position of the mask is fixed relative to the one or more substrates.

11. The system of claim 10 wherein said mask is carried by said substrate carrier.

12. The system of claim 10 wherein one or more of the substrates rotate so that the substrate surface moves relative to the substrate carrier surface, and wherein the position of the mask is fixed relative to the axis of rotation of each substrate.

13. In a thin film deposition system including (i) a sputtering target, (ii) one or more substrates carried by a substrate carrier past the sputtering target, and (iii) a mask, the improvement wherein the position of the mask is variable relative to the sputtering target.

14. The system of claim 13 wherein the position of the mask is fixed relative to the one or more substrates.

15. The system of claim 14 wherein the mask is carried by the substrate carrier.

16. The system of claim 13 wherein the mask alters the deposition of material sputtered from said target so that the thickness of the layer of deposited material is substantially uniform on the exposed surface of the substrates.

17. The system of claim 13 wherein the mask alters the deposition of material sputtered from said target so that the thickness of the layer of deposited material is selectively non-uniform on the exposed surface of the substrates.

18. A thin film deposition system comprising:
a deposition chamber;
a sputtering target positioned within the chamber forming a sputtering deposition zone;
a substrate carrier positioned within the chamber for moving one or more substrates through the sputtering deposition zone; and
a mask carried by said substrate carrier.

19. The system of claim 18 wherein the substrate carrier is a disk or a drum having a substrate mounting surface, said carrier being rotatable to position a portion of said substrate mounting surface in the sputtering deposition zone.

20. The system of claim 19 wherein the mask is positioned relative to the substrates so that the rate of deposition on exposed surface of the substrates is substantially uniform.

21. The system of claim 19 wherein the mask is positioned relative to the substrates so that the rate of deposition on exposed surface of the substrates is selectively non-uniform.

22. A thin film deposition system comprising:
a deposition chamber;
an elongated sputtering target positioned within said chamber, said target generating a flux of deposition material along the length of the target;
a substrate carrier for moving one or more substrates past said target so that the substrates are exposed to said flux of deposition material; and
a mask for partially shielding a portion of the substrates from the flux of deposition material.

23. A thin film deposition system comprising:
a deposition chamber;
a sputtering target; and
a substrate carrier for carrying one or more substrates past said sputtering target, said substrate carrier comprising one or more substrate carrying cells having a means for holding a substrate and a mask for shielding at least a portion of the substrate mounted in the cell from a portion of material sputtered from said sputtering target.

24. The system of claim 23 wherein one or more of said substrate carrying cells comprises a means for rotating the substrate relative to said carrier.

25. The system of claim 24 wherein said one or more substrate carrying cells are adapted to rotate a lamp burner about its longitudinal axis.

26. The system of claim 25 wherein said mask is positioned so that the material is deposited substantially uniformly on the surface of a lamp burner carried in the cell.

27. The system of claim 23 wherein said mask is positioned so that the material is deposited selectively non-uniformly on the surface of a lamp burner carried in the cell.

28. In a system for depositing a layer of material on an array of substrates carried on a substrate carrier past one or more sources of deposition material, a method of improving the uniformity of the layer deposited on the substrates comprising the step of masking each substrate with a mask having a position fixed relative to the substrate.

29. The method of claim 28 comprising the step of rotating the array of substrates past the one or more sources of deposition material on a surface of a disk or a drum.

30. The method of claim 29 comprising the step of concurrently rotating each substrate about its longitudinal axis.

31. The method of claim 30 wherein the array of substrates includes lamp burners.

32. The method of claim 28 wherein the substrates are carried on a generally cylindrical surface rotating about its longitudinal axis, and wherein the step of masking includes the step of providing substantially planar masks extending radially outward from the generally cylindrical surface.

33. The method of claim 28 wherein the substrates are carried on a generally planar surface rotating about an axis perpendicular thereto, and wherein the step of masking includes the step of providing substantially planar masks extending perpendicular to the surface.

34. In a thin film deposition system including an elongated sputtering target having a generally planar sputtering surface and a mask positioned over at least a portion of the sputtering surface having a plurality of surfaces extending substantially perpendicular thereto, the improvement wherein one or more of the mask surfaces extends farther from the sputtering surface than one or more of the other mask surfaces.

35. The system of claim 34 wherein the length of extension of one or more mask surfaces may be selectively varied.

36. The system of claim 34 wherein the mask comprises a grid of cells formed by intersecting blades.

37. The system of claim 36 wherein the depth of a portion of one or more blades may be selectively varied.

38. The system of claim 36 wherein the thickness of one or more blades may vary along the depth thereof.

39. The system of claim 36 wherein the cells are rectangular in cross-section.

40. In a thin film deposition system including an elongated sputtering target having a generally planar sputtering surface and a mask positioned over at least a portion of the sputtering surface formed by a plurality of blades extending substantially perpendicular thereto, the improvement the thickness of one or more blades is not uniform.

41. The system of claim 40 wherein one or more blades includes a wedge-shaped attached near one longitudinal edge thereof.

42. In a thin film deposition system including an elongated sputtering target having a generally planar sputtering surface and a mask positioned over at least a portion of the sputtering surface formed by a plurality of blades extending substantially perpendicular thereto, the improvement the depth of the one or more blades is not uniform.

43. The system of claim 42 wherein the depth of one or more blades may be selectively changed in one or more portions along the length thereof.

44. In a thin film deposition system including an elongated sputtering target having a generally planar sputtering surface generating a flux of deposition material that varies along the length thereof, a method of improving the uniformity of the flux adjacent a surface to be coated comprising the steps of positioning a mask over at least a portion of the sputtering surface formed by a plurality of blades extending substantially perpendicular thereto and selectively varying the depth or width of the blades.
